(19) United States
(12) Patent Application Publication
(10) Pub. No.: US 2026/0247951 A1
(43) Pub. Date: Aug. 20, 2026

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 19/647,070

(22) Filed: Apr. 14, 2026

Related U.S. Application Data
(63) Continuation of application No. PCT/JP2023/037787, filed on Oct. 19, 2023.

(51) Int. Cl. H10W 20/43; H10D 84/85; H10W 20/20; H10W 20/40

(52) U.S. Cl. CPC H10W 20/43; H10D 84/851; H10W 20/211; H10W 20/481

(57) ABSTRACT

A semiconductor device includes a substrate; a first power supply line extending in a first direction in plan view on a first surface of the substrate; a first conductive wall and a second conductive wall formed in the substrate and extending in the first direction shifted from the first power supply line in a second direction different from the first direction in plan view; a first semiconductor layer and a second semiconductor layer provided on a second surface of the substrate on an opposite side of the first surface and overlapping with the first power supply line in plan view; a first through via formed in the substrate and connecting the first power supply line and the second semiconductor layer; a third semiconductor layer formed over the first semiconductor layer; and a fourth semiconductor layer formed over the second semiconductor layer.

### CROSS-REFERENCE TO RELATED APPLICATION

The present application is a continuation application of International Application No. PCT/JP2023/037787 filed on October 19, 2023, the contents of which are incorporated herein by reference in their entirety.

### FIELD

The present disclosure relates to a semiconductor device.

### BACKGROUND

There is a technology referred to as CFET (Complementary Field Effect Transistor) which forms a CMOS (Complementary Metal-Oxide-Semiconductor) by arranging transistors in a direction perpendicular to a substrate. The CFET greatly reduces the area occupied by a CMOS basic cell and miniaturizes a semiconductor device. In a technology referred to as BS-PDN (Backside Power Delivery Network) which supplies a power supply voltage to a circuit on the front surface of a semiconductor substrate from the back surface of the substrate, there is a case in which a structure in which a Through Silicon Via (TSV) penetrating the substrate is directly connected to the source/drain of a transistor is used. There is a technology referred to as a power wall in which a conductive wall is formed over the height of upper and lower transistors of a CFET to supply power to each transistor. There is a technology in which a power switch circuit for controlling on/off of supply of a power supply voltage is provided in a circuit such as a standard cell.

### RELATED ART DOCUMENTS

### Patent Documents

Patent Document 1: U.S. Patent Application Publication No. 2022/0068921

Patent Document 2: U.S. Patent Application Publication No. 2023/0178435

Patent Document 3: U.S. Patent Application Publication No. 2023/0067311

Patent Document 4: U.S. Patent Application Publication No. 2022/0123023

Patent Document 5: U.S. Patent Application Publication No. 2022/0181258

Patent Document 6: WO 2020/065916

Patent Document 7: WO 2020/066797

Patent Document 8: WO 2020/217396

Patent Document 9: WO 2020/217400

Patent Document 10: U.S. Patent Application Publication No. 2021/0366902

Patent Document 11: U.S. Patent Application Publication No. 2022/0102479

Patent Document 12: U.S. Patent Application Publication No. 2021/0210600

Patent Document 13: U.S. Patent No. 10950546

Patent Document 14: U.S. Patent No. 11004789

How a power switch circuit is to be laid out in a circuit for supplying power to a CFET by a power wall has not been studied in detail.

### SUMMARY

In one embodiment, a semiconductor device includes a substrate; a first power supply line extending in a first direction in plan view on a first surface of the substrate; a first conductive wall and a second conductive wall formed in the substrate and extending in the first direction shifted from the first power supply line in a second direction different from the first direction in plan view; a first semiconductor layer and a second semiconductor layer provided on a second surface of the substrate on an opposite side of the first surface and overlapping with the first power supply line in plan view; a first through via formed in the substrate and connecting the first power supply line and the second semiconductor layer; a third semiconductor layer formed over the first semiconductor layer; a fourth semiconductor layer formed over the second semiconductor layer; a first gate provided between the first semiconductor layer and the second semiconductor layer and between the third semiconductor layer and the fourth semiconductor layer; a first transistor including the first semiconductor layer, the second semiconductor layer, and the first gate; and a control circuit configured to control the first transistor, wherein the first semiconductor layer is electrically connected to the first conductive wall, the control circuit includes a fifth semiconductor layer and a sixth semiconductor layer formed on the second surface and overlapping with the first power supply line in plan view; a seventh semiconductor layer formed over the fifth semiconductor layer; an eighth semiconductor layer formed over the sixth semiconductor layer; a second gate provided between the fifth semiconductor layer and the sixth semiconductor layer and between the seventh semiconductor layer and the eighth semiconductor layer; a second transistor including the fifth semiconductor layer, the sixth semiconductor layer, and the second gate; and a third transistor including the seventh semiconductor layer, the eighth semiconductor layer, and the second gate, the fifth semiconductor layer is electrically connected to the first conductive wall, and one of the seventh semiconductor layer or the eighth semiconductor layer is electrically connected to the second conductive wall; and another of the seventh semiconductor layer or the eighth semiconductor layer is electrically connected to the sixth semiconductor layer and the first gate of the first transistor.

The object and advantages of the invention will be implemented and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a schematic diagram illustrating an outline of a layout of a semiconductor device of an embodiment;

FIG. 2 is a schematic cross-sectional view illustrating an example of a wiring structure of a circuit region of a semiconductor device;

FIG. 3 is a schematic diagram illustrating an outline of a semiconductor device of an embodiment;

FIG. 4 is a plan view of a backside wiring layer (BSM: Backside Metal) of a semiconductor device of an embodiment;

FIG. 5 is a plan view of a bottom layer of a semiconductor device of an embodiment;

FIG. 6 is a plan view of a top layer of a semiconductor device of an embodiment;

FIG. 7 is a cross-sectional view X1-X1' of FIGS. 4 and 6;

FIG. 8 is a cross-sectional view Y1-Y1' of FIGS. 4 and 6; and

FIG. 9 is a plan view of a top layer of a semiconductor device of a modified example.

### DESCRIPTION OF EMBODIMENTS

A semiconductor device having a power switch circuit efficiently laid out in a configuration in which power is supplied by a power wall, is implemented.

In an embodiment, a power switch circuit is efficiently laid out in a semiconductor device in which a power wall is used as a part of a power supply line for supplying a power voltage to a CFET. In particular, an efficient arrangement relationship between a control circuit for controlling switching of supply of a power voltage to a standard cell, and the power wall, is implemented. Hereinafter, a specific configuration of the semiconductor device of the embodiment will be described with reference to the drawings. The embodiments described below are examples for implementing the technical concept of the present disclosure and are not intended to limit the contents of the disclosure. The sizes and positional relationships of the components illustrated in the drawings may be exaggerated to facilitate understanding of the invention. In some cases, the same components or functions are given the same names or reference numerals and redundant descriptions are omitted.

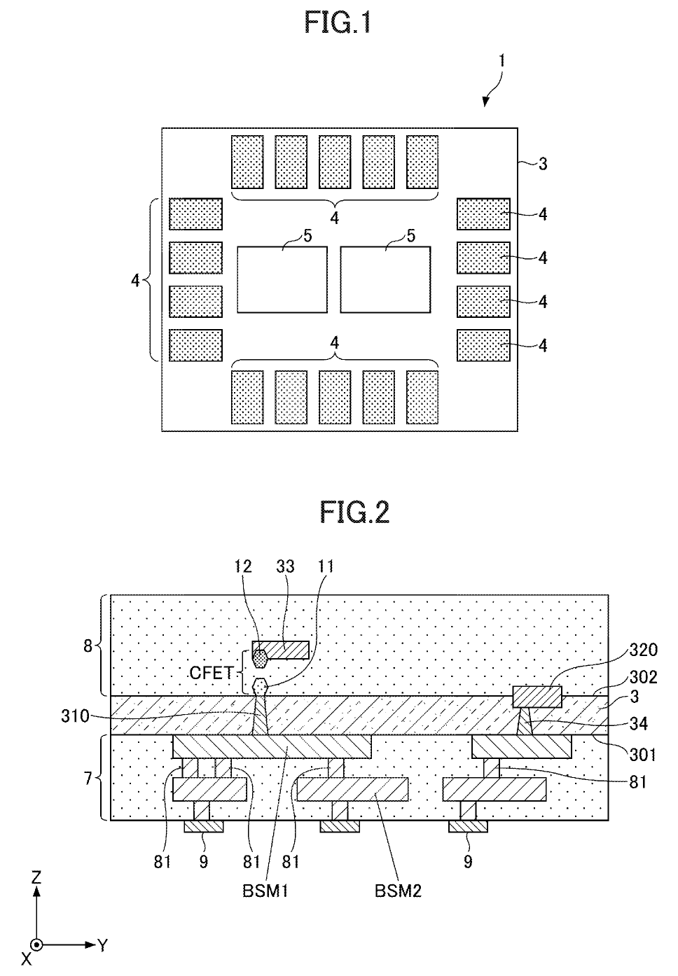

FIG. 1 is a schematic diagram illustrating an outline of a layout of a semiconductor device 1 according to an embodiment. The semiconductor device 1 has one or more circuit regions 5 provided on a substrate 3 and a plurality of input/output (I/O) cell regions 4 arranged on the substrate 3. The circuit region 5 may have a standard cell including a plurality of logic circuits, or may have other circuits such as a gate array, SRAM (Static Random Access Memory), and analog circuits.

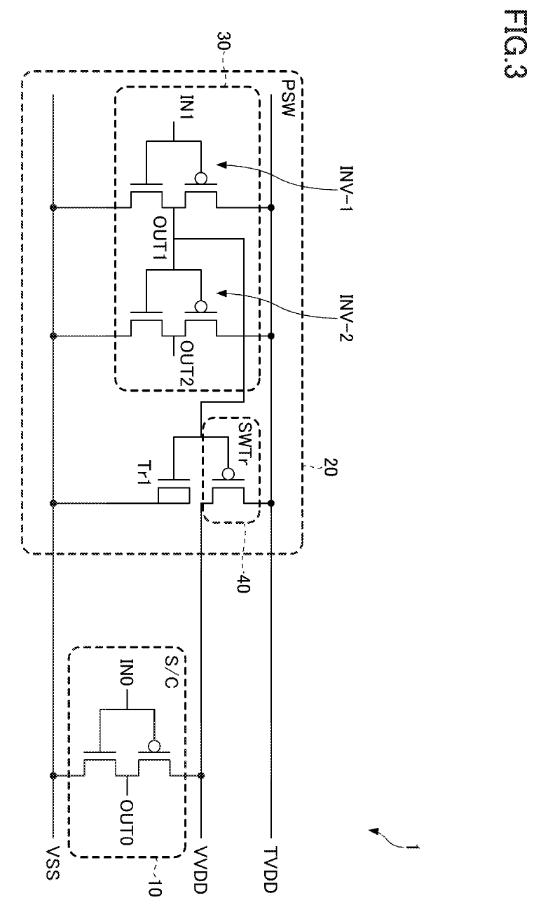

FIG. 2 is a schematic cross-sectional view illustrating an example of a wiring structure of the circuit region 5 of the semiconductor device 1. In the coordinate system of FIG. 2, the plane parallel to the substrate 3 is the XY plane, and the direction perpendicular to the substrate 3, that is, the lamination direction is the Z direction. The semiconductor device 1 has a first wiring layer 7 on the back surface 301 side of the substrate 3 and a second wiring layer 8 on the front surface 302 side of the substrate. The semiconductor device 1 supplies a power supply voltage from the back surface 301 of the substrate 3 to a circuit on the front surface 302 side of the substrate 3. Here, the back surface 301 of the substrate 3 is referred to as a “first surface” and the front surface 302 is referred to as a “second surface”. A CFET in which a first transistor 11 and an upper transistor 12 are arranged in a direction perpendicular to the substrate 3 is formed on the front surface 302 side of the substrate 3. The first transistor 11 may be referred to as a “bottom transistor” and the upper transistor may be referred to as a “top transistor”. In this figure, the source and drain (hereinafter referred to as “source/drain” as appropriate) of the bottom transistor 11 and the top transistor 12 are extended in the X direction perpendicular to the paper surface.

In the first wiring layer 7, a power supply line for supplying an operating voltage of the circuit and a power supply line for supplying a reference voltage lower than the operating voltage are formed. In the example illustrated in FIG. 2, a first layer wiring (BSM1) on the back surface 301 of the substrate 3 and a second layer wiring (BSM2) on the back surface 301 are provided. The first layer wiring BSM1 and the second layer wiring BSM2 are connected by a via plug 81. A pad 9 serving as an external connection terminal is formed on the lowermost surface of the first wiring layer 7. The first wiring layer 7 may be a wiring layer directly formed on the back surface 301 of the substrate 3, or may be a wiring layer formed on another chip (i.e., a substrate) bonded to the back surface 301 of the substrate 3.

The wirings BSM1 and BSM2 of the first wiring layer 7 are connected to the semiconductor layer of the first transistor 11 of the CFET by a through via 310 penetrating the substrate 3. The wirings BSM1 and BSM2 of the first wiring layer 7 are electrically connected to the top transistor 12 of the CFET by a through via (not illustrated) provided in the substrate 3 and a wiring 33 formed in the second wiring layer 8. An embedded wiring 320 connected to the through via 34 may be provided on the front surface 302 side of the substrate 3. The connection between the wirings on the back surface 301 of the substrate 3 and the top transistor 12 of the CFET may be implemented by a conductive wall (also referred to as a “power wall”) extending vertically from the back surface 301 to the front surface 302 side of the substrate 3 and the wiring 33 connected to the conductive wall, as described below.

<Outline of a semiconductor device of an embodiment>

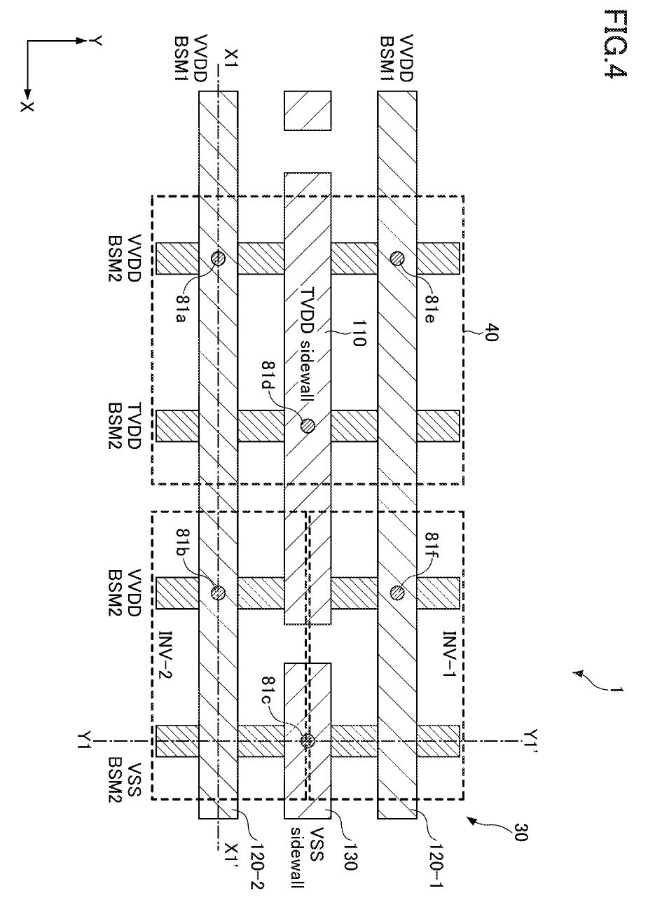

FIG. 3 is a diagram illustrating an outline of a semiconductor device 1. The semiconductor device 1 includes a standard cell 10 and a power switch circuit (denoted as “PSW” in the figure) 20 for turning on and off the supply of a power supply voltage to the standard cell 10. The standard cell 10 has a minimum unit circuit formed of various logic circuits such as NAND, NOR, AOI (AND-OR INV), and flip-flop. In the example of FIG. 3, the standard cell 10 is an inverter, but the present invention is not limited to this example, and other logic circuits may be used.

The power switch circuit 20 includes a switch transistor (denoted as “SWTr” in the figure) 40 for turning on and off the supply of a power supply voltage to the standard cell 10, and a control circuit 30 for controlling the switch transistor 40. In a configuration in which the power switch circuit 20 turns on and off the supply of a power supply voltage to a circuit such as the standard cell 10, three types of power supply lines are used: true VDD (TVDD), virtual VDD (VVDD), and VSS. TVDD and VVDD supply an operating voltage of the circuit. VSS supplies a reference voltage lower than VDD. As will be described below, at least one of the power supply lines TVDD or VSS has a conductive wall (or power wall) perpendicular to the substrate.

The standard cell 10 is electrically connected between VSS and VVDD. The power switch circuit 20 is electrically connected between VSS and TVDD. If the power supply voltage is always supplied to the standard cell 10 even when the standard cell 10 is not in use, leakage may occur and power consumption may increase. In order to suppress this, the standard cell 10 is connected to a virtual power supply line VVDD, and the power supply voltage is supplied from the TVDD to the VVDD when necessary. The power supply from the TVDD to the VVDD to which the standard cell is connected is executed by the switch transistor 40 based on an instruction from the control circuit 30. In this example, the switch transistor 40 is composed of a PMOS transistor, and its source is connected to the TVDD and its drain is connected to the VVDD. When the signal IN0 is input to the gate of the standard cell 10 while the power supply voltage is supplied to the VVDD, the signal OUT0 is output from the drains of the PMOS and NMOS.

The control circuit 30 has, for example, an inverter INV-1 and an inverter INV-2. Each of the inverters INV-1 and INV-2 may have a CFET structure. When the signal IN1 is input to the gate of the inverter INV-1 of the preceding stage, the signal “OUT 1” is output from the inverter INV-1. The signal “OUT 1” is input to the gate of the inverter INV-2 of the succeeding stage and is input to the gate of the switch transistor 40 as an output of the control circuit 30. A signal “OUT 2” is output from the inverter INV-2 of the succeeding stage, to the outside. The switch transistor 40 turns on and off the supply of the power supply voltage from TVDD to VVDD based on the signal “OUT 1” from the control circuit 30. In the configuration example of FIG. 3, the switch transistor 40 is controlled by the signal “OUT 1” from the node between the inverters INV-1 and INV-2, but the configuration is not limited to this example. Any configuration for controlling on and off the supply of the power supply voltage to the switch transistor 40, such as using a single inverter, can be adopted.

A transistor Tr1 similar to an NMOS is connected to the gate of the switch transistor 40 formed of PMOS. The switch transistor 40 and the transistor Tr1 may form a CFET which is arranged in a direction perpendicular to the substrate and connected to a common gate. In FIG. 3, portions corresponding to the source and drain of the transistor Tr1 are connected to the VSS, but may be floating. The transistor Tr1 may be a dummy top transistor formed by a process common to the standard cell 10 and the CFET of the control circuit 30. When the top transistor does not function as an element, the formation of the top transistor may be omitted instead of forming a dummy transistor.

When switching on/off the supply of the power supply voltage to the standard cell 10 in a circuit using three types of power supply lines, i.e., TVDD, VVDD, and VSS, it is important how to design the specific wiring of the power switch circuit 20. Because the VSS wiring is formed as a conductive wall (power wall) rising in a direction perpendicular to the front surface 302 of the substrate 3 and is connected to both the power switch circuit 20 and the standard cell 10, an efficient connection structure is required. When the TVDD is formed as a conductive wall rising in a direction perpendicular to the front surface 302 of the substrate 3, an efficient layout of the power switch circuit 20 connected between the TVDD and the VSS is required.

<Specific Configuration of a Semiconductor Device>

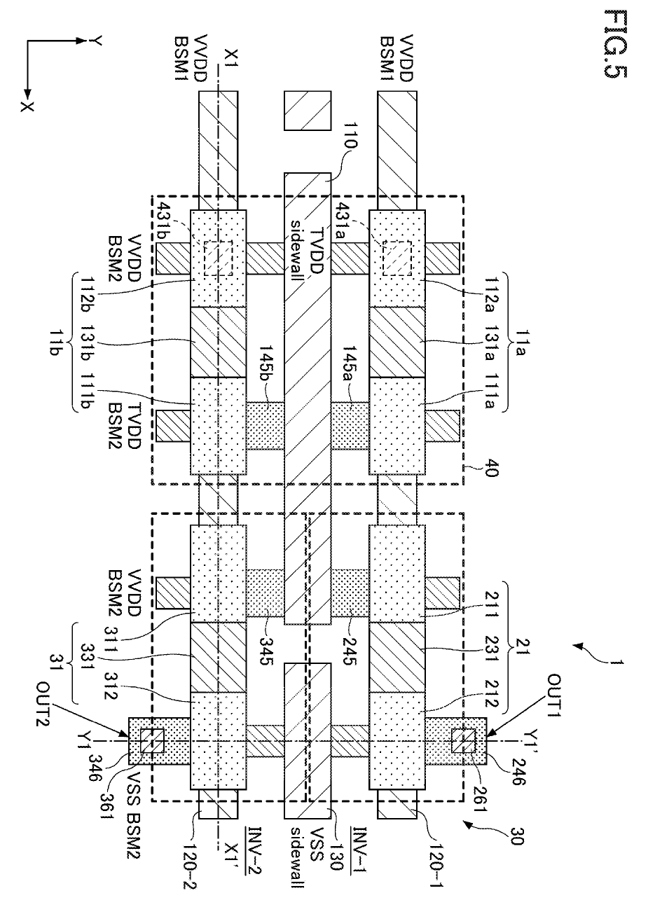

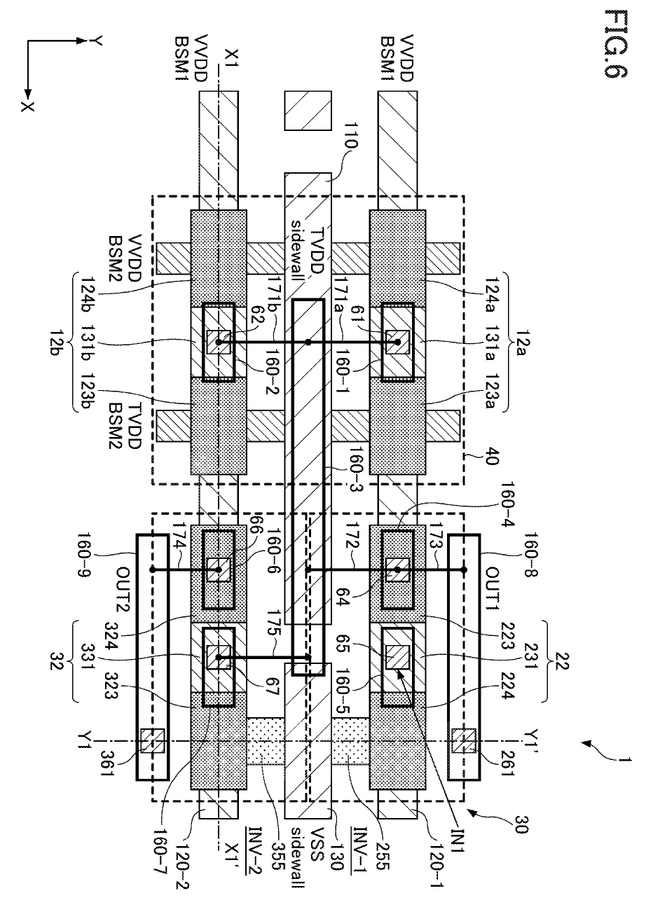

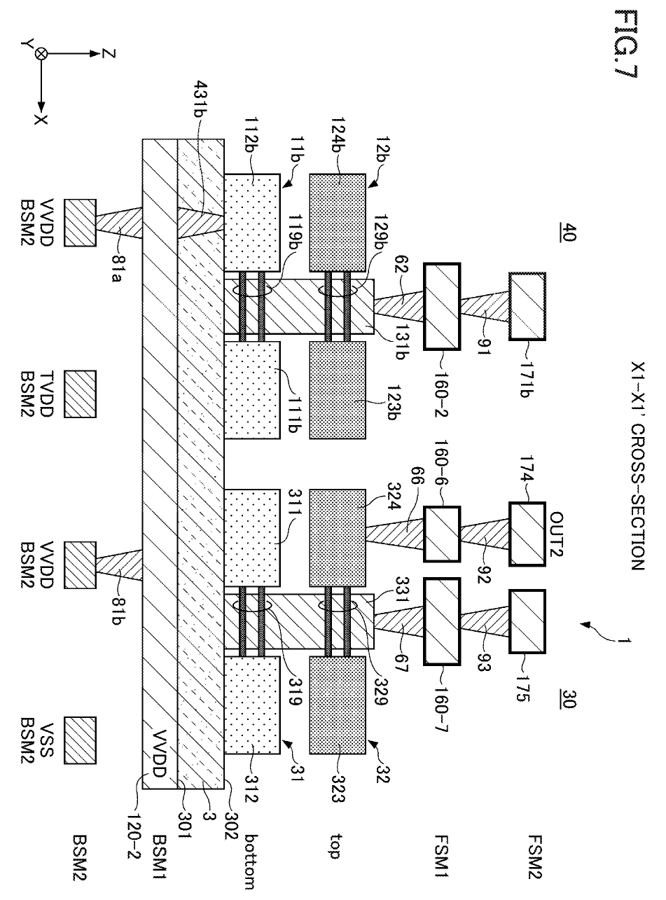

FIG. 4 is a plan view of the BSM of the semiconductor device 1 of the embodiment, FIG. 5 is a plan view of the bottom layer, and FIG. 6 is a plan view of the top layer. The BSM is a wiring layer included in the first wiring layer 7 on the back surface 301 side of the substrate 3 (see FIG. 2), the bottom layer is a layer including the first transistor 11 of the CFET provided on the front surface 302 side of the substrate 3, and the top layer is a layer including the top transistor 12 of the CFET. In the coordinate axes of FIGS. 4 to 6 and FIG. 9, a direction indicated by an arrow indicating an X direction or a Y direction is referred to as a plus (+) direction, and a direction opposite to the plus direction is referred to as a minus (-) direction.

### Example of Planar Arrangement of BSM

In FIG. 4, a VVDD 120-1, which is a power supply line extending in the X direction in plan view, is provided on the back surface 301 of the substrate 3, and a TVDD sidewall 110 and a VSS sidewall 130 extending in the X direction are arranged offset from the VVDD 120-1 in a direction orthogonal to the X direction. The TVDD sidewall 110 and the VSS sidewall 130 are arranged side by side with a predetermined interval in the X direction. The TVDD sidewall 110 may be arranged at a position where the VSS sidewall 130 is interrupted. Depending on the configuration of the control circuit 30, a VVDD 120-2 extending in the X direction may be arranged on a side opposite to the VVDD 120-1 with the TVDD sidewall 110 and the VSS sidewall 130 interposed therebetween. In this example, the VVDD 120-2 is provided to secure a region for arranging the inverters INV-1 and INV-2 of the control circuit 30 of FIG. 3.

The TVDD sidewall 110 and the VSS sidewall 130 extend in the X direction between the VVDD 120-1 and 120-2 in a region corresponding to the control circuit 30. The TVDD sidewall 110 extends in the X direction between the VVDD 120-1 and 120-2 in a region corresponding to the switch transistor 40. The TVDD sidewall 110 supplies an operating voltage of the circuit, and the VSS sidewall 130 supplies a reference voltage lower than the operating voltage. In this example, the TVDD sidewall 110 and the VSS sidewall 130 are conductive walls that penetrate the substrate 3 from the back surface 301 of the substrate 3 and reach a height greater than or equal to the height of the CFET on the front surface 302 side.

The TVDD sidewall 110 and the VSS sidewall 130 may be conductive walls that rise from the front surface of the substrate 3 to the height of the CFET top transistor. In this case, a through via formed in the substrate 3 may be connected to the TVDD sidewall 110 and the VSS sidewall 130, and a power supply voltage may be supplied to the TVDD sidewall 110 and the VSS sidewall 130 via the through via. Further, either one of the TVDD sidewall 110 or the VSS sidewall 130 may be arranged as a power supply line formed on the back surface of the substrate 3.

In the back surface second layer (BSM2) of the substrate 3, TVDD, VVDD, and VSS wirings extending in the Y direction are formed (referred to as "TVDD BSM2”, "VVDD BSM2", and "VSS BSM2" respectively in the figure). The TVDD sidewall 110 is connected to the TVDD BSM2 by a via plug 81d. In a region where the switch transistor 40 is provided, the VVDD 120-1 and 120-2 are connected to the VVDD BSM2 extending in the Y direction within the region of the switch transistor 40 by via plugs 81e and 81a, respectively. In a region where the control circuit 30 is provided, the VSS sidewall 130 is connected to the VSS BSM2 by a via plug 81c. The VVDD 120-1 and 120-2 are connected to the VVDD BSM2 extending in the Y direction within the region of the control circuit 30 by via plugs 81f and 81b, respectively.

### Example of Planar Arrangement of Bottom Layer

FIG. 5 is a plan view of the bottom layer of the front surface 302 of the substrate 3. The TVDD sidewall 110 and the VSS sidewall 130 extending in the X direction penetrate the substrate 3 and have, for example, a height greater than or equal to the height of the CFET on the front surface 302 side. In the region of the switch transistor 40, a first semiconductor layer 111a and a second semiconductor layer 112a are provided which overlap the VVDD 120-1 on the back surface in plan view. The first semiconductor layer 111a is connected to the TVDD sidewall 110 by a wiring 145a protruding in the -Y direction. The second semiconductor layer 112a is connected to the VVDD 120-1 on the back surface 301 of the substrate 3 by a through via 431a penetrating the substrate 3. A gate 131a is provided between the first semiconductor layer 111a and the second semiconductor layer 112a to form a first transistor 11a.

In the Y direction, a first semiconductor layer 111b and a second semiconductor layer 112b are provided on the opposite side of the VVDD 120-1 across the TVDD sidewall 110 and overlap the VVDD 120-2 on the back surface in plan view. The first semiconductor layer 111b is connected to the TVDD sidewall 110 by a wiring 145b protruding in the +Y direction. The second semiconductor layer 112b is connected to the VVDD 120-2 on the back surface 301 of the substrate 3 by a through via 431b penetrating the substrate 3. A gate 131b is provided between the first semiconductor layer 111b and the second semiconductor layer 112b to form a first transistor 11b.

A first conductivity type (e.g., p-type) impurity is added to the first semiconductor layers 111a and 111b and the second semiconductor layers 112a and 112b. One of the first semiconductor layer 111a or the second semiconductor layer 112a functions as a source, and the other functions as a drain. Whether the first semiconductor layer 111a or the second semiconductor layer 112a is used as a source or a drain depends on the design of the wiring. Similarly, one of the first semiconductor layer 111b or the second semiconductor layer 112b functions as a source, and the other functions as a drain. Whether the first semiconductor layer 111b or the second semiconductor layer 112b is used as a source or a drain depends on the design of the wiring. As will be described below with reference to FIG. 6, the gate 131a of the first transistor 11a and the gate 131b of the first transistor 11b provided on either side of the TVDD sidewall 110 are electrically connected, and the first transistors 11a and 11b are connected in parallel.

In the region of the control circuit 30, a fifth semiconductor layer 211 and a sixth semiconductor layer 212 are provided which overlap the VVDD 120-1 on the back surface in plan view. Impurities of the first conductivity type are added to the fifth semiconductor layer 211 and the sixth semiconductor layer 212. A gate 231 is provided between the fifth semiconductor layer 211 and the sixth semiconductor layer 212, and a bottom transistor 21 (second transistor) of the inverter INV-1 in the preceding stage is formed. The fifth semiconductor layer 211 of the bottom transistor 21 is connected to the TVDD sidewall 110 by a wiring 245 projecting in the -Y direction. The sixth semiconductor layer 212 is connected to a wiring 246 projecting in the +Y direction. A via plug 261 is connected to the wiring 246, and a signal “OUT 1” of the bottom transistor 21 is taken out to a wiring of an upper layer.

On the opposite side of the TVDD sidewall 110 and the VSS sidewall 130, a source 311 and a drain 312, which are semiconductor layers overlapping the VVDD 120-2 on the back surface in plan view, are provided. Impurities of the first conductivity type are added to the source 311 and the drain 312. A gate 331 is provided between the source 311 and the drain 312, and a bottom transistor 31 of the inverter INV-2 of the succeeding stage is formed. The source 311 of the bottom transistor 31 is connected to the TVDD sidewall 110 by a wiring 345 projecting in the +Y direction, and the drain 312 is connected to a wiring 346 projecting in the −Y direction. A via plug 361 is connected to the wiring 346, and a signal “OUT 2” of the bottom transistor 31 is taken out to an upper layer wiring.

A signal “OUT 1” output from the bottom transistor 21 of the inverter INV-1 is input to the gate 131a of the first transistor 11a and the gate 131b of the first transistor 11b together with a signal “OUT 1” output from a top transistor to be described below. When the first transistors 11a and 11b are on, a power supply voltage is supplied from the TVDD sidewall 110 to the VVDD 120-1 and 120-2. Thus, the power supply voltage is supplied to the standard cell 10, and the standard cell operates.

### Planar Configuration Example of Top Layer

FIG. 6 is a plan view of the top layer of the front surface 302 of the substrate 3. In the region of the switch transistor 40, a third semiconductor layer 123a is provided above the first semiconductor layer 111a, and a fourth semiconductor layer 124a is provided above the second semiconductor layer 112a. A gate 131a used in common with the first transistor 11a is provided between the third semiconductor layer 123a and the fourth semiconductor layer 124a, and a top transistor 12a is formed. The gate 131a of the top transistor 12a is connected by a via plug 61 to an upper layer wiring 160-1, and receives a signal “OUT 1” output from the inverter INV-1 of the control circuit 30.

On the opposite side of the TVDD sidewall 110 in the Y direction, a third semiconductor layer 123b is provided above the first semiconductor layer 111b of the first transistor 11b, and a fourth semiconductor layer 124b is provided above the second semiconductor layer 112b. A gate 131b used in common with the first transistor 11b is provided between the third semiconductor layer 123b and the fourth semiconductor layer 124b, and a top transistor 12b is formed. The gate 131b of the top transistor 12b is connected by a via plug 62 to an upper layer wiring 160-2, and receives a signal “OUT 1” output from the inverter INV-1 of the control circuit 30.

A second conductivity type (e.g., n-type) impurity different from the first conductivity type is added to the third semiconductor layers 123a and 123b and the fourth semiconductor layers 124a and 124b of the top transistors 12a and 12b. The third semiconductor layers 123aand 123b and the fourth semiconductor layers 124a and 124b are floating in this example, but may be electrically connected to the VSS sidewall 130 through, for example, a wiring or via plug (not illustrated). In the present invention, portions that do not operate as transistors, such as the top transistors 12a and 12b, are referred to as transistors in some cases.

In the region of the control circuit 30, a seventh semiconductor layer 223 and an eighth semiconductor layer 224 are provided above the fifth semiconductor layer 211 and the sixth semiconductor layer 212 of the bottom transistor 21, respectively. A gate 231 used in common with the bottom transistor 21 is arranged between the seventh semiconductor layer 223 and the eighth semiconductor layer 224. The top transistor 22 (third transistor) of the inverter INV-1 is formed by the seventh semiconductor layer 223, the eighth semiconductor layer 224, and the gate 231. One of the seventh semiconductor layer 223 or the eighth semiconductor layer 224 is connected to the VSS sidewall 130 by a wiring 255 projecting in the -Y direction, and the other of the seventh semiconductor layer 223 or the eighth semiconductor layer 224 is connected to a via plug 64 to output a signal “OUT 1” of the top transistor 22. In this example, the eighth semiconductor layer 224 is connected to the VSS sidewall 130 by a wiring 255, and the seventh semiconductor layer 223 outputs a signal “OUT 1” to an upper layer wiring 160-4 via a via plug 64. The gate 231 is connected to an upper layer wiring 160-5 by a via plug 65. The via plug 261 electrically connected to the sixth semiconductor layer 212 of the bottom transistor 21 is connected to an upper layer wiring 160-8.

A top transistor 32 of an inverter INV-2 is formed on the opposite side of the TVDD sidewall 110 and the VSS sidewall 130 in the Y direction. The top transistor 32 has a drain 324 provided above the source 311 of the bottom transistor 31 and a source 323 provided above the drain 312 of the bottom transistor 31. A gate 331 used in common with the bottom transistor 31 is arranged between the source 323 and the drain 324, and the top transistor 32 of the inverter INV-2 is formed. The source 323 of the inverter INV-2 is connected to the VSS sidewall 130 by a wiring 355 projecting in the +Y direction. The gate 331 is connected to the upper layer wiring 160-7 by a via plug 67. The drain 324 is connected to the upper layer wiring 160-6 by a via plug 66. The via plug 361 electrically connected to the drain 312 of the bottom transistor 31 is connected to the upper layer wiring 160-9.

The upper layer wiring 160-3 overlapping the TVDD sidewall 110 and the VSS sidewall 130 in plan view is electrically connected to the gates 131a and 131b of the first transistors 11a and 11b, the seventh semiconductor layer 223 serving as the drain of the top transistor 22 of the inverter INV-1, and the gate 331 of the inverter INV-2. In the inverter INV-1, the upper layer wiring 160-4 electrically connected to the seventh semiconductor layer 223 is further connected to the upper layer wiring 160-3 by the upper layer wiring 172, and further connected to the upper layer wiring 160-8 by the upper layer wiring 173. The upper layer wiring 160-8 is electrically connected to the sixth semiconductor layer 212 of the bottom transistor 21 by the via plug 261. When the signal “IN 1” is input to the gate 231 of the inverter INV-1, the signal “OUT 1” output from the bottom transistor 21 and the top transistor 22 is taken out as an output signal of the inverter INV-1.

In the region of the switch transistor 40, the upper layer wiring 160-3 is further connected to the gate 131a of the first transistor 11a by the upper layer wiring 171a, the upper layer wiring 160-1, and the via plug 61. The upper layer wiring 160-3 is also connected to the gate 131b of the first transistor 11b by the upper layer wiring 171b, the upper layer wiring 160-2, and the via plug 62. The signal “OUT 1” output from the inverter INV-1 is supplied to the switch transistor 40 through the upper layer wirings 160-8, 160-4, and 160-3, and is input to the gates 131aand 131b. When the first transistors 11aand 11bare on, a power supply voltage is supplied from the TVDD sidewall 110 to the VVDD 120-1 and 120-2.

In the inverter INV-2, the upper layer wiring 160-7 electrically connected to the gate 331 is connected to the upper layer wiring 160-3 by the upper layer wiring 175. The upper layer wiring 160-6 electrically connected to the drain 324 is further connected to the upper layer wiring 160-9 by the upper layer wiring 174.

With the configuration illustrated in FIGS. 4, 5, and 6, the switch transistor 40 of the power switch circuit 20 and the control circuit 30 for controlling the switch transistor 40 can be efficiently arranged in the vicinity of the TVDD sidewall 110 and the VSS sidewall 130.

### <Cross-Sectional Structure>

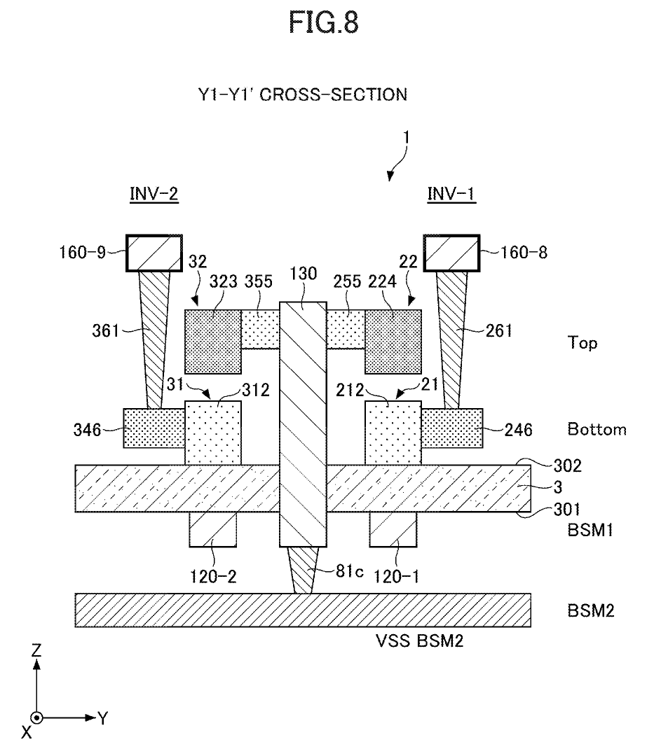

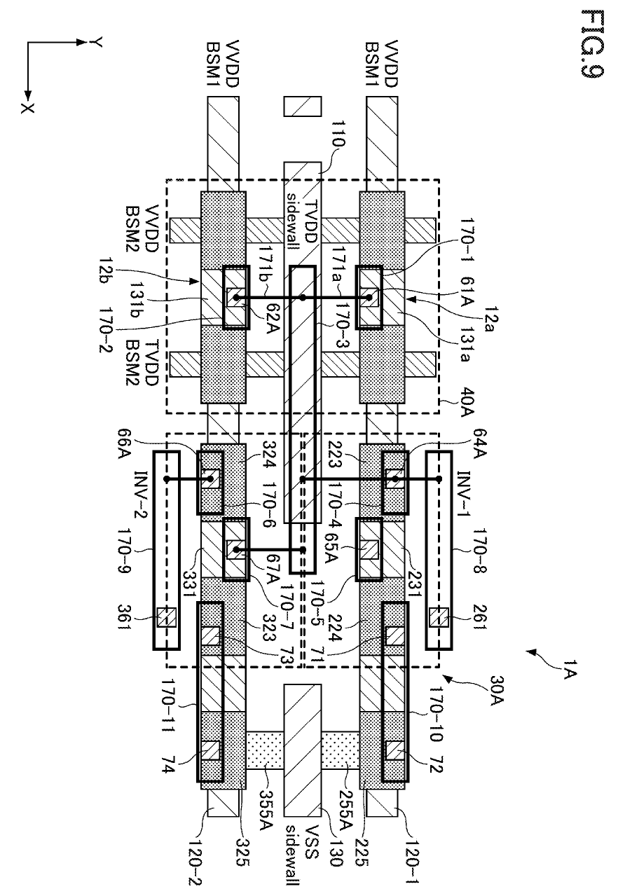

FIG. 7 is a cross-sectional view taken along X1 – X1’ and FIG. 8 is a cross-sectional view taken along Y1 – Y1’, of FIGS. 4 to 6. The cross section X1 – X1’ is a vertical cross section along the VVDD 120-2, and the cross section Y1 – Y1’ is a vertical cross section along a line perpendicular to the X1 – X1’ line and passing through the wirings 255 and 355 connected to the VSS sidewall 130.

In the cross section X1 – X1’ of FIG. 7, the VVDD 120-2 is arranged in the X direction in the first layer wiring (BSM1) of the back surface 301 of the substrate 3. The VVDD 120-1 is connected to the VVDD BSM2 which is a wiring extending in the Y direction in the back surface second layer via via plugs 81a and 81b.

A first semiconductor layer 111b and a second semiconductor layer 112b overlapping with the VVDD 120-2 in plan view are provided in the region of the switch transistor 40 on the front surface 302 side of the substrate 3. The second semiconductor layer 112b is connected to the VVDD 120-2 on the back surface 301 by a through via 431b penetrating the substrate 3. A third semiconductor layer 123b is provided above the first semiconductor layer 111b, and a fourth semiconductor layer 124b is provided above the second semiconductor layer 112b. The first semiconductor layer 111b and the second semiconductor layer 112b are connected by a channel 119b of a nanosheet. The third semiconductor layer 123b and the fourth semiconductor layer 124b are connected by a channel 129b of a nanosheet.

A common gate 131 is arranged between the first semiconductor layer 111b and the second semiconductor layer 112b, and between the third semiconductor layer 123b and the fourth semiconductor layer 124b. The gate 131 is connected to an upper layer wiring 160-2 by a via plug 62. The upper layer wiring 160-2 is connected to a further upper layer wiring 171 by a via plug 91.

A source 311 and a drain 312 of a bottom transistor 31 of an inverter INV-2 are formed in a region of a control circuit 30 on the front surface 302 side of a substrate 3, overlapping with a VVDD 120-2 in plan view. A drain 324 and a source 323 of a top transistor 32 are provided above the source 311 and the drain 312, respectively. A common gate 331 is arranged between the source 311 and the drain 312, and between the source 323 and the drain 324. The source 311 and the drain 312 of the bottom transistor 31 are connected by a channel 319 of a nanosheet. The source 323 and the drain 324 of the top transistor 32 are connected by a channel 329 of a nanosheet.

The drain 324 of the top transistor 32 is connected to an upper layer wiring 160-6 by a via plug 66. The upper layer wiring 160-6 is electrically connected to an upper layer wiring 174 by a via plug 92, and a signal “OUT 2” output from the inverter INV-2 is taken outside. A gate 331 commonly used for the bottom transistor 31 and the top transistor 32 of the inverter INV-2 is connected to an upper layer wiring 160-7 by a via plug 67. The upper layer wiring 160-7 is connected to the upper layer wiring 175 by a via plug 93.

In the cross section Y1 − Y1’ of FIG. 8, VVDD 120-1 and 120-2 are formed on the back surface 301 of the substrate 3 with a VSS sidewall 130 interposed therebetween. The VSS sidewall 130 is connected to VSS BSM2 formed on the second layer of the back surface 301 by a via plug 81c.

A sixth semiconductor layer 212 overlapping the VVDD 120-1 in plan view is formed in the region of the inverter INV-1 on the front surface 302 of the substrate 3. The sixth semiconductor layer 212 is used as a drain of the bottom transistor 21. An eighth semiconductor layer 224 is formed above the sixth semiconductor layer 212. A wiring 246 projects from the sixth semiconductor layer 212 in the +Y direction, and a signal “OUT 1” of the bottom transistor 21 is extracted to an upper layer wiring 160-8 by a via plug 261. The eighth semiconductor layer 224 is connected to the VSS sidewall 130 by a wiring 255 projecting in the −Y direction.

In the region of the inverter INV-2, the drain 312 of the bottom transistor 31 is formed at a position overlapping the VVDD 120-2 in plan view. A source 323 of the top transistor 32 is formed above the drain 312. A wiring 346 projects from the drain 312 in the -Y direction, and a signal “OUT 2” of the bottom transistor 31 is taken out to an upper layer wiring 160-9 by a via plug 361. The signal “OUT2” of the bottom transistor 31 is taken out to an upper layer wiring 160-9 together with the signal “OUT2” output from the drain of the top transistor 32, and is output to the outside as a signal “OUT2” of the inverter INV-2. The source 323 of the top transistor 32 is connected to the VSS sidewall 130 by a wiring 355 projecting in the +Y direction.

With this cross-sectional configuration, the control circuit 30 having a CFET structure can be efficiently arranged in the vicinity of the VSS sidewall 130.

<Modified example>

FIG. 9 is a plan view of a top layer of a semiconductor device 1A according to a modified example. The semiconductor device 1A has a switch transistor 40A and a control circuit 30A for controlling the switch transistor 40A. In the modified example of FIG. 9, in the control circuit 30A, the sources of the top transistors of the inverters INV-1 and INV-2 are connected to the VSS sidewall 130 via a relay semiconductor layer. Further, the via plugs for connecting the gates or semiconductor layers (source/drain) of the respective transistors to the upper layer wiring are provided shifted in the Y direction and/or X direction within an allowable range.

In the switch transistor 40A, the gate 131a of the first transistor 11a provided on one side in the Y direction across the TVDD sidewall 110 is connected to the upper layer wiring 170-3 extending in the X direction by the via plug 61A, the upper layer wiring 170-1, and the upper layer wiring 171a. The gate 131b of the first transistor 11b provided on the other side in the Y direction across the TVDD sidewall 110 is connected to the upper layer wiring 170-3 by the via plug 62A, the upper layer wiring 170-2, and the upper layer wiring 171b.

The via plug 61A may be shifted in the −Y direction compared with the via plug 64A, and the via plug 62A may be shifted in the +Y direction compared with the via plug 66A. Further, the upper layer wiring 170-1 may be shifted in the −Y direction compared with the upper layer wiring 170-4, and the upper layer wiring 170-2 may be shifted in the +Y direction compared with the upper layer wiring 170-6.

In the inverter INV-1 of the control circuit 30A, a seventh semiconductor layer 223, an eighth semiconductor layer 224, and a relay semiconductor layer 225 are formed in this order in the X direction, overlapping the VVDD 120-1 in plan view. Via plugs 64A, 71, and 72 are connected to the seventh semiconductor layer 223, the eighth semiconductor layer 224, and the relay semiconductor layer 225, respectively. The via plugs 71 and 72 may be shifted in the +Y direction as compared with the via plug 61A.

In the inverter INV-2, a drain 324, a source 323, and a relay semiconductor layer 325 are formed in this order in the X direction, overlapping the VVDD 120-2 in plan view. Via plugs 66A, 73, and 74 are connected to the drain 324, the source 323, and the relay semiconductor layer 325, respectively. The via plugs 73 and 74 may be shifted in the −Y direction as compared with the via plug 62A.

The relay semiconductor layer 225 is connected to the VSS sidewall 130 by a wiring 255A projecting in the −Y direction. The relay semiconductor layer 225 is electrically connected to the eighth semiconductor layer 224 via the via plug 72, the upper layer wiring 170-10, and the via plug 71.

The relay semiconductor layer 325 is connected to the VSS sidewall 130 by a wiring 355A projecting in the +Y direction. The relay semiconductor layer 325 is electrically connected to the source 323 via the via plug 74, the upper layer wiring 170-11, and the via plug 73.

By electrically connecting the 8th semiconductor layer 224 and the source 323 to the VSS sidewall 130 via the relay semiconductor layers 225 and 325, it is possible to supply a reference voltage on the low voltage side to the transistor of the control circuit 30A even when the interval in the X direction between the TVDD sidewall 110 and the VSS sidewall 130 needs to be increased.

The via plug 65A connected to the gate 231 of the inverter INV-1 and the upper layer wiring 170-5 may be shifted in the -Y direction with respect to the via plug 64A and the upper layer wiring 170-4. The via plug 67A connected to the gate 331 of the inverter INV-2 and the upper layer wiring 170-7 may be shifted in the +Y direction with respect to the via plug 67A and the upper layer wiring 170-7.

Although the configuration of a semiconductor device has been described based on specific configuration examples, the present disclosure is not limited to the configuration examples described above. Which of the semiconductor layers provided on either side of the gate is used as a source and which is used as a drain in each of the bottom and top transistors forming each CFET, is determined by design. In the switch transistor 40 or 40A, a plurality of first transistors 11a or 11b may be connected in parallel on each side of the TVDD sidewall 110 to increase the scale of the switch transistor 40 or 40A. In this case, a large current can flow. The configuration of the embodiment and the modified example implements an efficient layout of the control circuit 30 and the switch transistor 40 when the CFET is located near the TVDD sidewall and/or the VSS sidewall.

What is claimed is:

1. A semiconductor device comprising:
a substrate;
a first power supply line extending in a first direction in plan view on a first surface of the substrate;
a first conductive wall and a second conductive wall formed in the substrate and extending in the first direction shifted from the first power supply line in a second direction different from the first direction in plan view;
a first semiconductor layer and a second semiconductor layer provided on a second surface of the substrate on an opposite side of the first surface and overlapping with the first power supply line in plan view;
a first through via formed in the substrate and connecting the first power supply line and the second semiconductor layer;
a third semiconductor layer formed over the first semiconductor layer;
a fourth semiconductor layer formed over the second semiconductor layer;
a first gate provided between the first semiconductor layer and the second semiconductor layer and between the third semiconductor layer and the fourth semiconductor layer;
a first transistor including the first semiconductor layer, the second semiconductor layer, and the first gate; and
a control circuit configured to control the first transistor, wherein
the first semiconductor layer is electrically connected to the first conductive wall,
the control circuit includes:
a fifth semiconductor layer and a sixth semiconductor layer formed on the second surface and overlapping with the first power supply line in plan view;
a seventh semiconductor layer formed over the fifth semiconductor layer;
an eighth semiconductor layer formed over the sixth semiconductor layer;
a second gate provided between the fifth semiconductor layer and the sixth semiconductor layer and between the seventh semiconductor layer and the eighth semiconductor layer;
a second transistor including the fifth semiconductor layer, the sixth semiconductor layer, and the second gate; and
a third transistor including the seventh semiconductor layer, the eighth semiconductor layer, and the second gate,
the fifth semiconductor layer is electrically connected to the first conductive wall, and
one of the seventh semiconductor layer or the eighth semiconductor layer is electrically connected to the second conductive wall; and another of the seventh semiconductor layer or the eighth semiconductor layer is electrically connected to the sixth semiconductor layer and the first gate of the first transistor.

2. The semiconductor device according to claim 1, further comprising:
a first wiring protruding from the fifth semiconductor layer in the second direction and connecting to the first conductive wall; and
a second wiring protruding from one of the seventh semiconductor layer or the eighth semiconductor layer in the second direction and connecting to the second conductive wall.

3. The semiconductor device according to claim 2, further comprising:
a third wiring protruding from the first semiconductor layer in the second direction and connecting to the first conductive wall.

4. The semiconductor device according to claim 1, wherein, in plan view, two of the first power supply lines are provided at an interval in the second direction, and the first conductive wall and the second conductive wall are arranged in the first direction between the two first power supply lines.

5. The semiconductor device according to claim 4, wherein a plurality of the first transistors are provided sandwiching the first conductive wall in the second direction.

6. The semiconductor device according to claim 1, wherein the first conductive wall and the second conductive wall are arranged side by side in the first direction.

7. The semiconductor device according to claim 1, wherein the first conductive wall is arranged between two of the second conductive walls arranged in the first direction.

8. The semiconductor device according to claim 1, further comprising:
a relay semiconductor layer overlapping the first power supply line in plan view, wherein
the relay semiconductor layer electrically connects one of the seventh semiconductor layer or the eighth semiconductor layer to the second conductive wall.

9. The semiconductor device according to claim 8, further comprising:
a fourth wiring connecting the relay semiconductor layer and the second conductive wall, wherein
one of the seventh semiconductor layer or the eighth semiconductor layer is electrically connected to the second conductive wall by the relay semiconductor layer and the fourth wiring.

10. The semiconductor device according to claim 1, wherein the third semiconductor layer and the fourth semiconductor layer are electrically connected to the second conductive wall.
